(19) United States
(12) Patent Application Publication
(10) Pub. No.: US 2015/0155518 A1
(43) Pub. Date: Jun. 4, 2015

(54) ORGANIC LIGHT EMITTING DISPLAY DEVICE

(71) Applicant: LG Display Co., Ltd., Seoul (KR)

(72) Inventor: Hyunsuk KIM, Gyeonggi-do (KR)

(73) Assignee: LG Display Co., Ltd., Seoul (KR)

(21) Appl. No.: 14/557,679

(22) Filed: Dec. 2, 2014

(30) Foreign Application Priority Data
Dec. 2, 2013 (KR) 10-2013-0148536

(51) Int. Cl. H01L 51/50

(52) U.S. Cl. CPC H01L 51/5028

(57) ABSTRACT

An organic light-emitting display device is disclosed. The organic light-emitting display device includes an emission layer formed between two electrodes disposed over a substrate, wherein the emission layer includes a host including fluorescent materials and a dopant including phosphorescent materials, and a host PL region formed by the host of the fluorescent materials has a spectrum overlapped with part of a dopant UV absorption region formed by the dopant of the phosphorescent materials.

### CROSS-REFERENCE TO RELATED APPLICATION

Pursuant to 35 U.S.C. §119(a), this application claims the benefit of earlier filing date and right of priority to Korean Patent Application No. 10-2013-0148536, filed on Dec. 2, 2013, the contents of which are incorporated by reference herein in their entirety.

### BACKGROUND OF THE INVENTION

1. Field of the Invention

The present invention relates to an organic light-emitting display device.

2. Discussion of the Related Art

An organic light-emitting element used in an organic light-emitting display device is an emissive element in which an emission layer is formed between two electrodes placed on a substrate.

An organic light-emitting display device includes a top-emission method, a bottom-emission method, and a dual-emission method depending on the direction in which light is emitted.

An organic light-emitting display device adopts a method of implementing an image using organic light-emitting elements that emit red, green, and blue light and a method of implementing an image using an organic light-emitting element that emits white light and red, green, and blue color filters.

The light-emitting materials of an organic light-emitting display device may maximize performance using a host-dopant system. In this case, an important factor is smooth energy transition from the host to the dopant.

Energy transition attributable to a dipole interaction is chiefly generated in fluorescent materials, and energy transition attributable to the mutual exchange of electrons is chiefly generated in phosphorescent materials. However, if energy transition attributable to a dipole interaction is generated in the phosphorescent materials, problems, such as a narrow viewing angle and low efficiency, are generated because the energy transition is not smooth due to a complicated energy level. Accordingly, there is a need to improve the problems.

### SUMMARY OF THE INVENTION

Accordingly, the present invention is directed to an organic light emitting display device that substantially obviated one or more of the problems to due limitations and disadvantages of the related art.

An object of the present invention is to provide an organic light emitting display device with increased viewing angle.

Another object of the present invention is to provide an organic light emitting display device with improved efficiency.

Additional features and advantages of the invention will be set forth in the description which follows, and in part will be apparent from the description, or may be learned by practice of the invention. The objectives and other advantages of the invention will be realized and attained by the structure particularly pointed out in the written description and claims here of as well as the appended drawings.

To achieve these and other advantages and in accordance with the purpose of the invention, as embodied and broadly described, an organic light-emitting display device comprises an emission layer formed between two electrodes disposed over a substrate, wherein the emission layer includes a host including fluorescent materials and a dopant including phosphorescent materials, and a host PL region formed by the host of the fluorescent materials has a spectrum overlapped with part of a dopant UV absorption region formed by the dopant of the phosphorescent materials.

It is to be understood that both the foregoing general description and the following detailed description are exemplary and explanatory and are intended to provide further explanation of the invention as claimed.

### BRIEF DESCRIPTION OF THE DRAWINGS

The accompany drawings, which are included to provide a further understanding of the invention and are incorporated in and constitute a part of this specification illustrate embodiments of the invention and together with the description serve to explain the principles of the invention. In the drawings:

FIG. 1 is a schematic plan view of an organic light-emitting display device;

FIG. 2 is an exemplary diagram illustrating the configuration of a subpixel circuit illustrated in FIG. 1;

FIG. 3 is an exemplary diagram illustrating a cross section of the subpixel of FIG. 1;

FIG. 4 is a diagram illustrating a method of forming an emission layer;

FIG. 5 is a cross-sectional hierarchy diagram of the emission layer formed using the method of FIG. 4;

FIG. 6 is a graph illustrating measured values according to the sharpness of the wavelengths of a related art display panel implemented using a phosphorescent dopant;

FIG. 7 is a diagram illustrating energy transition attributable to a dipole interaction between a host and a dopant;

FIG. 8 is a graph illustrating measured values according to the sharpness of the wavelengths of a display panel implemented using a phosphorescent dopant in accordance with an embodiment of the present invention;

FIG. 9 is a graph illustrating EL spectra for a comparison between the related art display panel and the display panel in accordance with an embodiment of the present invention;

FIG. 10 is a graph illustrating viewing angles for a comparison between the related art display panel and the display panel in accordance with an embodiment of the present invention; and

FIG. 11 is a graph illustrating a difference between viewing angles according to the characteristics of host materials.

### DETAILED DESCRIPTION OF THE EMBODIMENTS

Reference will now be made in detail to embodiments of the invention some examples of which are illustrated in the accompanying drawings.

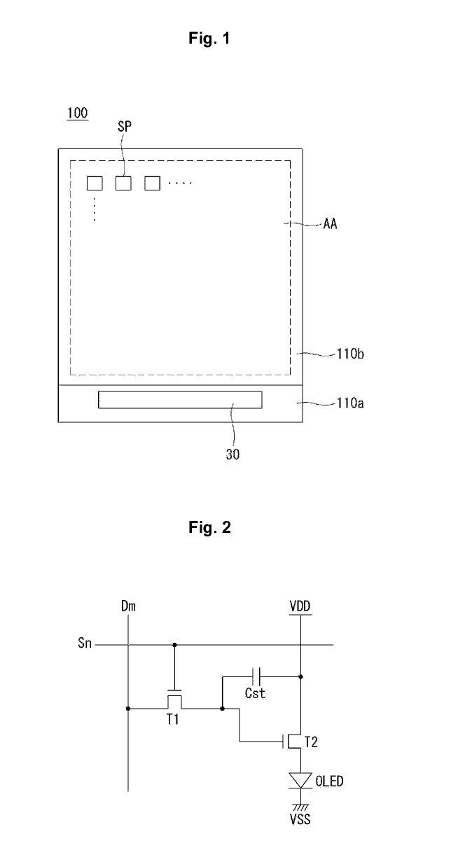

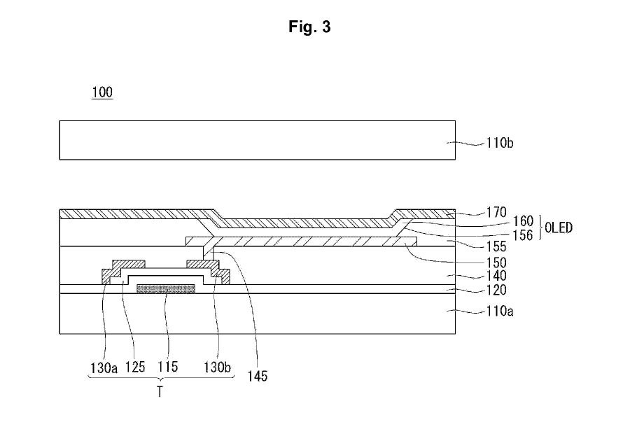

FIG. 1 is a schematic plan view of an organic light-emitting display device, FIG. 2 is an exemplary diagram illustrating the configuration of a subpixel circuit illustrated in FIG. 1, and FIG. 3 is an exemplary diagram illustrating a cross section of the subpixel of FIG. 1.

As illustrated in FIG. 1, a display panel 100 that forms an organic light-emitting display device includes a display unit AA including a plurality of subpixels SP formed on a first substrate 110a. The display unit AA formed on the first substrate 110a is sealed by a second substrate 110b.

A driving unit 30 is formed on the first substrate 110a and configured to drive the plurality of subpixels SP included in the display unit AA. The driving unit 30 may include a data driving unit configured to supply data signals to the plurality of subpixels SP and a scan driving unit configured to supply scan signals. In this case, the scan driving unit may be separated from the data driving unit and may be formed in the outskirts of the display unit AA in a GIP form.

As illustrated in FIG. 2, the subpixel SP may include a switching thin film transistor T1 configured to transfer a data signal supplied through a data line Dm in response to a scan signal supplied by a scan line Sn, a capacitor Cst configured to store the data signal, a driving thin film transistor T2 configured to generate a driving current corresponding to a difference between the data signal stored in the capacitor Cst and a first power source voltage VDD, and an organic light-emitting diode (OLED) configured to emit light corresponding to the driving current.

The switching thin film transistor T1, the capacitor Cst, and the driving thin film transistor T2 may be defined as a transistor unit. The transistor unit has been illustrated as being a 2T(Transistor)1C(Capacitor) including two thin film transistors and a single capacitor. In some embodiments, the transistor unit may be configured to include N (N is an integer of 2 or more) thin film transistors and M (M is an integer of 2 or more) capacitors in order to compensate for a threshold voltage, etc. In FIG. 2, VSS is a second power source voltage, that is, a ground voltage or lower.

The subpixel SP includes a method of implementing an image using OLEDs that emit red, green, and blue light and a method of implementing an image using an OLED that emits white light and red, green, and blue color filters. In the following description, a subpixel formed using the method of implementing an image using OLEDs that emit red, green, and blue light is taken as an example.

As illustrated in FIG. 3, the transistor unit T and the OLED included in the subpixel are deposited on the first substrate 110a in a thin film form.

A gate electrode 115 is formed on the first substrate 110a. The gate electrode 115 may be made of one selected from the group consisting of molybdenum (Mo), aluminum (Al), chromium (Cr), gold (Au), titanium (Ti), nickel (Ni), and copper (Cu) or an alloy of them. The gate electrode 115 may have a single layer or a multi-layer.

A first insulating film 120 for providing the gate electrode 115 with insulation is formed on the gate electrode 115. The first insulating film 120 may be a silicon oxide (SiOx) film, a silicon nitride (SiNx) film, or a dual layer of them.

A semiconductor layer 125 is formed over the gate electrode 115 and the first insulating film 120 corresponding to the gate electrode 115. The semiconductor layer 125 may be made of amorphous silicon (a-Si), poly-Si, oxide, or an organic material.

A source electrode 130a and a drain electrode 130b are formed on the semiconductor layer 125 and are electrically connected to the semiconductor layer 125. The source electrode 130a and the drain electrode 130b may be made of one selected from the group consisting of molybdenum (Mo), aluminum (Al), chromium (Cr), gold (Au), titanium (Ti), nickel (Ni), and copper (Cu) or an alloy of them. Each of the source electrode 130a and the drain electrode 130b may have a single layer or a multi-layer. An ohmic contact layer for reducing a contact resistance between the semiconductor layer 125 and the source electrode 130a, the drain electrode 130b may be formed between the semiconductor layer 125 and the source electrode 130a, the drain electrode 130b.

A second insulating film 140 is formed on the thin film transistor T including the gate electrode 115, the semiconductor layer 125, the source electrode 130a, and the drain electrode 130b. The second insulating film 140 may be a planarization film or a passivation film for reducing the step coverage of an underlying structure. The second insulating film 140 may be made of an organic material, such as polyimide, benzocyclobutene-series resin, or acrylate. The second insulating film 140 includes a via hole 145 through which part of the source electrode 130a or the drain electrode 130b is exposed.

A lower electrode 150 electrically connected to the source electrode 130a or the drain electrode 130b is formed on the second insulating film 140. The lower electrode 150 may be a transparent conductive film made of Indium Tin Oxide (ITO), Indium Zinc Oxide (IZO), Indium Tin Zinc Oxide (ITZO), Zinc Oxide (ZnO), Indium Gallium Zinc Oxide (IGZO), or graphene. The lower electrode 150 is selected as an anode electrode.

A bank layer 155 including an opening part 156 through which the lower electrode 150 is exposed is formed on the lower electrode 150. The bank layer 155 may be a pixel definition film that mitigates the step coverage of an underlying structure and defines an emission region. The bank layer 155 may be made of polyimide, benzocyclobutene-series resin, or acrylate.

An organic emission layer 160 is formed on the lower electrode 150. The organic emission layer 160 may be made of an organic material that emits red, green, and blue light. The organic emission layer 160 includes an emission layer EML and a common layer including a Hole Injection Layer (HIL), a Hole Transport Layer (HTL), an Electron Transport Layer (ETL), and an Electron Injection Layer (EIL) for improving characteristics. The common layer may not include all the four layers. In some embodiments, at least one of the four layers may be omitted from the common layer, or another function layer may be included in the common layer.

An upper electrode 170 is formed on the first substrate 110a including the organic emission layer 160. The upper electrode 170 may be made of aluminum (Al), silver (Ag), magnesium (Mg), or calcium (Ca), that is, metal having a low work function, or an alloy of them. The upper electrode 170 is selected as a cathode electrode.

The subpixel formed in the display panel 100 has been illustrated as adopting a bottom-emission method in which light is emitted in the direction of the first substrate 110a, but the present invention is not limited thereto. In some embodiments, the subpixel may be configured to adopt a top-emission method or a dual-emission method.

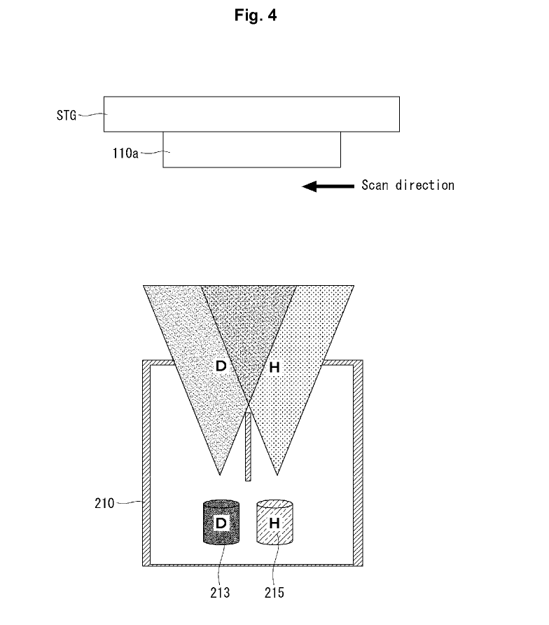

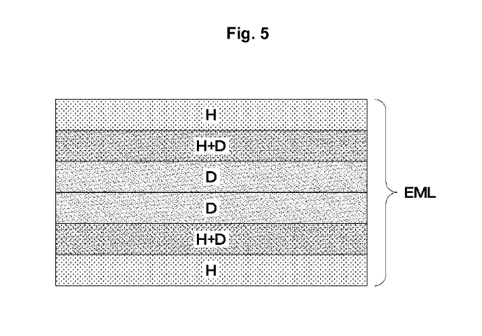

FIG. 4 is a diagram illustrating a method of forming the emission layer, and FIG. 5 is a cross-sectional hierarchy diagram of the emission layer formed using the method of FIG. 4.

As illustrated in FIG. 4, the emission layer of the OLED is formed using a method of simultaneously depositing a host and a dopant. An organic source unit 210 is disposed under a deposition apparatus.

A first source unit 213 including a dopant material D and a second source unit 215 including a host material H are disposed within the organic source unit 210. The first source unit 213 and the second source unit 215 disposed within the organic source unit 210 are physically separated from each other, but the sources D and H have a specific overlap area when they pass through the organic source unit 210 and fly in a target direction.

A stage STG moves along the top of the organic source unit 210 as if the stage scans the organic source unit 210 in the state in which the stage holds the first substrate 110a. The underlying electrodes of the transistor unit and the OLED have been formed on the first substrate 110a.

The stage STG may move over the organic source unit 210 as if the stage STG performs scanning from right to left, but is not limited thereto. For example, the stage STG may move in one direction (e.g., move from right to left) as if the stage STG performs scanning or may move in both directions (e.g., move from right to left and then move from left to right) as if the stage STG performs scanning.

The hierarchy of the host and the dopant that form the emission layer of the OLED may have various forms depending on the number of times of scanning of the stage STG.

As illustrated in FIG. 5, the emission layer EML of the OLED may have a hierarchy in which a host region H, a mixed region H+D in which the host and the dopant are mixed, a dopant region D, a dopant region D, a mixed region H+D in which the host and the dopant region are mixed, and a host region H are sequentially deposited from the bottom to the top.

The hierarchy structure of the emission layer EML of the OLED illustrated in FIG. 5 is obtained when the stage performs scanning once while moving from right to left. In general, when a host material and a dopant material are simultaneously deposited, the emission layer EML is divided into the dopant region D, the host region H, and the mixed region H+D. That is, a single region, such as the dopant region D or the host region H, other than the mixed region H+D is included in the emission layer EML.

If a single region, such as the dopant region D or the host region H, is present, the distance between the host and the dopant is increased and energy transition attributable to a dipole interaction is initiatively generated when phosphorescent materials are used. Problems related to such an increased distance and the initiative generation of energy transition attributable to a dipole interaction and a solution to them are described later.

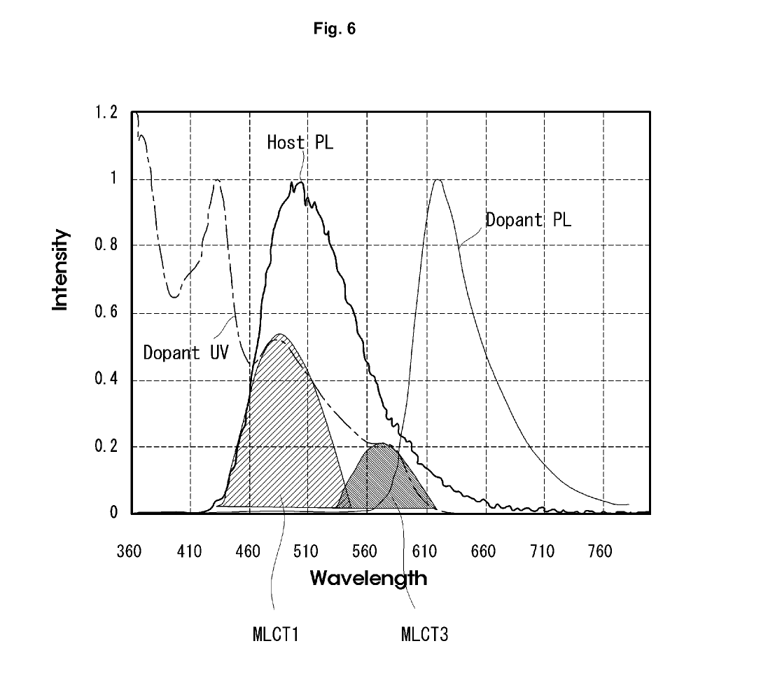

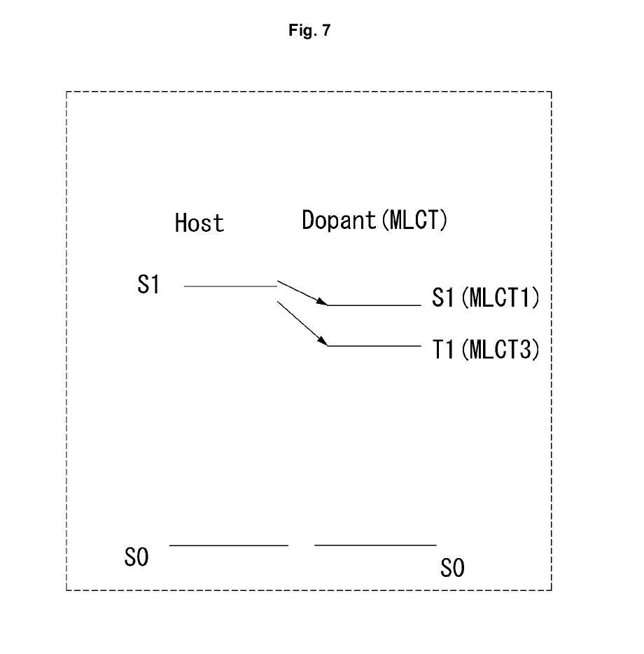

FIG. 6 is a graph illustrating measured values according to the sharpness of the wavelengths of a related art display panel implemented using a phosphorescent dopant, and FIG. 7 is a diagram illustrating energy transition attributable to a dipole interaction between a host and a dopant. In FIG. 6, a horizontal axis denotes the wavelengths of frequencies, and a vertical axis denotes sharpness or intensities.

As illustrated in FIGS. 6 and 7, in the related art display panel implemented using a phosphorescent dopant, Metal to Ligand Charge Transfer (MLCT) regions MLCT1 and MLCT3 in a dopant UV absorption region Dopant UV are present within a host photoluminescence (PL) region Host PL. The MLCT region means a region where dipole energy transition in which charges move in the empty ligand orbit of the dopant in the metal orbit of the host may occur. The MLCT1 region is the region of a singlet S1, and the MLCT3 region is the region of a triplet T1.

Such dipole energy transition when the host PL region Host PL is overlapped with the dopant UV absorption region Dopant UV in an ultraviolet region UV and a PL spectrum. In fluorescent materials, such dipole energy transition is generated in only one of the MLCT1 region and the MLCT3 region because such overlap is generated in only one of the MLCT1 region and the MLCT3 region. In contrast, in phosphorescent materials, such dipole energy transition is generated in both the MLCT1 region and the MLCT3 region because such overlap is generated in both the MLCT1 region and the MLCT3 region. That is, it has been theoretically known that energy transition may occur when the host PL region Host PL is overlapped with the MLCT1 region or the MLCT3 region in the dopant UV absorption region Dopant UV or when the host PL region Host PL is overlapped with both the MLCT1 region and the MLCT3 region.

However, an experiment revealed that energy transition was rarely generated in the MLCT3 region compared to the MLCT1 region and energy transition was also rarely generated between the MLCT1 region and the MLCT3 region. That is, energy transition is rarely generated when the host PL region Host PL is overlapped with both the MLCT1 region and the MLCT3 region of the dopant UV absorption region Dopant UV or is overlapped with the MLCT3 region. For this reason, if the host PL emits light in a region where efficiency is low or energy transition is rarely performed, a light emission (hereinafter abbreviated as “EL”) spectrum is changed, which deteriorates a viewing angle characteristic of a display panel.

In order to improve such a problem, in accordance with the present invention, the host PL region Host PL is overlapped with only the MLCT1 region in the phosphorescent dopant UV absorption Dopant UV based on the aforementioned experiment results so as to improve device characteristics. This is described below.

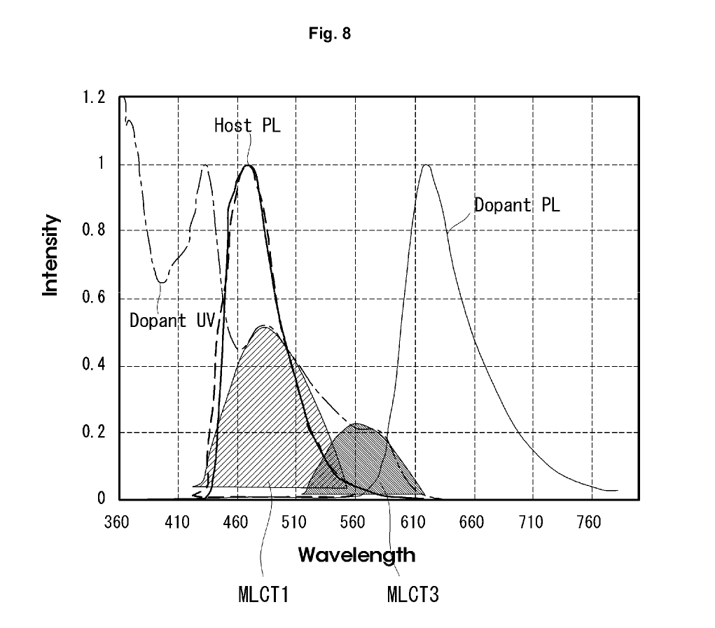

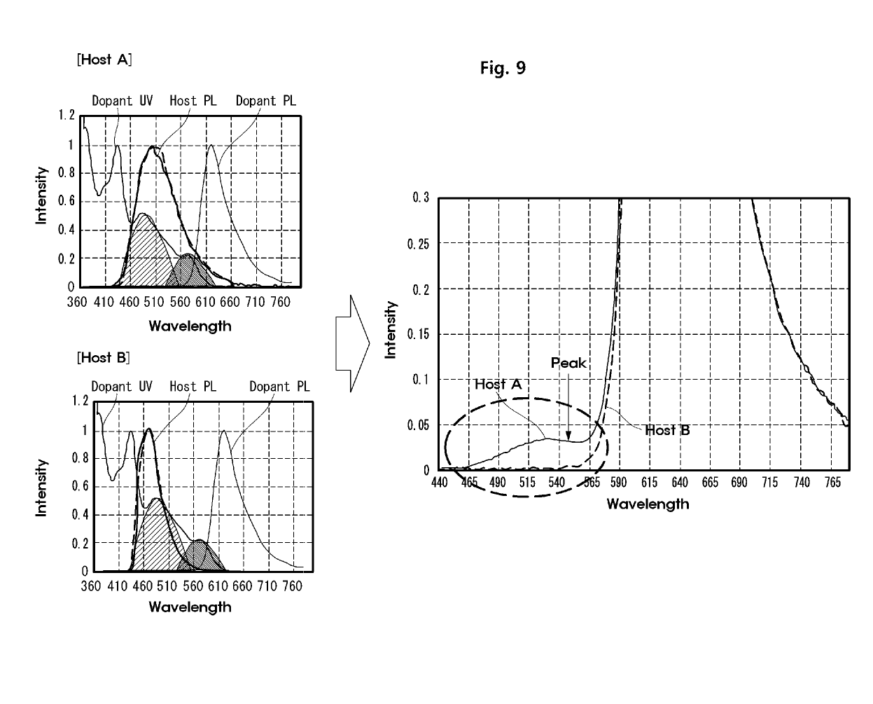

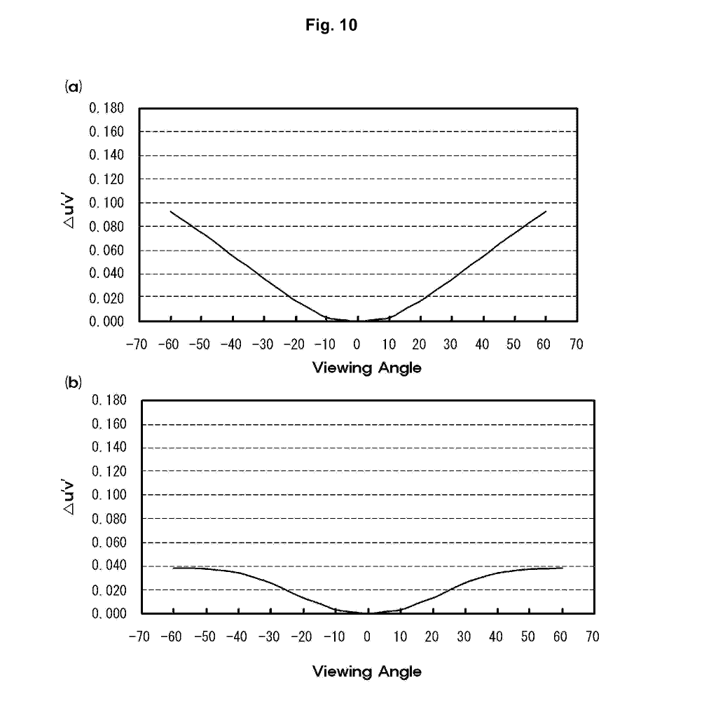

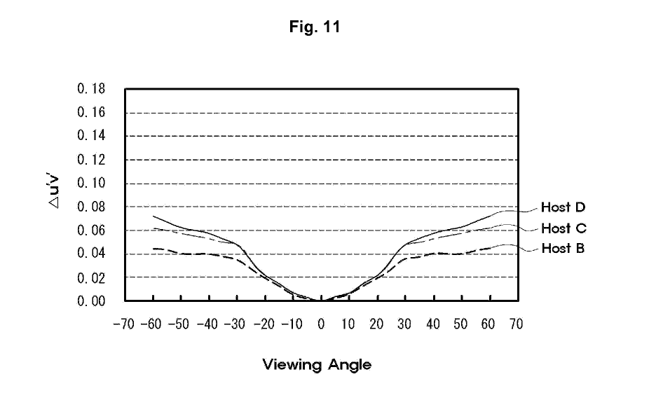

FIG. 8 is a graph illustrating measured values according to the sharpness of the wavelengths of a display panel implemented using a phosphorescent dopant in accordance with an embodiment of the present invention, FIG. 9 is a graph illustrating EL spectra for a comparison between the related art display panel and the display panel in accordance with an embodiment of the present invention, FIG. 10 is a graph illustrating viewing angles for a comparison between the related art display panel and the display panel in accordance with an embodiment of the present invention, and FIG. 11 is a graph illustrating a difference between viewing angles according to the characteristics of host materials. In FIGS. 8 and 9, a horizontal axis denotes the wavelengths of frequencies, and a vertical axis denotes sharpness or intensities.

As illustrated in FIG. 8, in accordance with an embodiment of the present invention, the MLCT1 region is present in the host PL region Host PL, but the MLCT3 region is not present in the host PL region Host PL. That is, the host PL region Host PL is overlapped with the MLCT1 region, but is not overlapped with the MLCT3 region.

However, only part of the MLCT3 region is present in the host PL region Host PL because the MLCT1 region and the MLCT3 region are partially overlapped with each other. More specifically, the host PL region Host PL is overlapped with the peak of the MLCT1 region, but is not overlapped with the peak of the MLCT3 region.

Furthermore, the half width of the host PL region Host PL is narrower than that of the MLCT1 region. Furthermore, the host PL region Host PL has a small overlap region (i.e., only a very small region is overlapped) to the extent that it is rarely overlapped with a dopant PL region Dopant PL.

In an embodiment of the present invention, only the MLCT1 region is present in the host PL region Host PL in such a manner that the structure of the emission layer including a host material is changed and a wavelength band occupied by the host PL region Host PL is narrowed. The host used in the experiment is fluorescent materials, and the dopant used in the experiments is phosphorescent materials. Furthermore, the dopant, that is, the phosphorescent materials, has a PL wavelength band of 380 nm˜780 nm.

As illustrated in FIG. 9, in a host A material Host A used in the related art display panel, the host PL region Host PL is overlapped with both the MLCT1 region and MLCT3 region of the dopant. For this reason, in the host A material Host A, an EL peak is generated in the host region as in a graph on the right side.

In contrast, in a host B material Host B used in the display panel in accordance with an embodiment of the present invention, the host PL region Host PL is overlapped with only the MLCT1 region of the dopant. For this reason, in the host B material Host B, an EL peak is not generated in the host region as in the graph on the right side.

A comparison and experiment were performed on efficiency of the host A material Host A used in the related art display panel and efficiency of the host B material Host B used in the display panel in accordance with an embodiment of the present invention, thereby obtaining the following data, such as that in Table 1 below.

TABLE 1

| | | Host B (present |
|---|---|---|
| Notes | Host A (related art) | invention) |
| Efficiency (cd/A) | 25 cd/A | 30 cd/A |

Furthermore, a comparison and experiment were performed on the viewing angle characteristic of the host A material Host A used in the related art display panel and the viewing angle characteristic of the host B material Host B used in the display panel in accordance with an embodiment of the present invention, thereby obtaining the following data, such as that of FIG. 10. In FIG. 10, a horizontal axis denotes a viewing angle, and a vertical axis denotes a color deviation Δu'v′ in chroma coordinates.

In accordance with Tables 1 and 10, the host A material Host A used in the related art display panel turned yellowish due to the EL peak generated in the host region, thus having a low viewing angle characteristic and low efficiency (refer to (a) of FIG. 10). In contrast, the host B material Host B in accordance with an embodiment of the present invention has the host PL region Host PL overlapped with only the MLCT1 region, thus having an improved viewing angle characteristic and improved efficiency compared to the host A material Host A (refer to (b) of FIG. 10).

A single experiment example using only the host B material Host B has been illustrated above. As can be seen from FIG. 11, however, such characteristics were obtained in a host C material Host C and a host D material Host D in addition to the host B material Host B.

Experiments using the host B material Host B to the host D material Host D revealed that a color deviation Δu'v′ in chroma coordinates was about 0.04˜0.08. Each of the host C material Host C and the host D material Host D also had the host PL region Host PL overlapped with only the MLCT1 region. It was found that the host C material Host C and the host D material Host D had an improved viewing angle characteristic and improved efficiency compared to the host A material Host A, but had a slightly improved viewing angle characteristic and efficiency compared to the host B material Host B.

As described above, the present invention is advantageous in that it can improve a viewing angle characteristic and efficiency because the spectrum region of a host is optimized by mixing and using the host including fluorescent materials and a dopant including phosphorescent materials and overlapping the host PL region with only one of phosphorescent dopant UV absorption regions.

It will be apparent to those skilled in the art that various modifications and variations can be made in the organic light emitting display device of the present invention without departing from the spirit or scope of the invention. Thus, it is intended that the present invention cover the modifications and variations of this invention provided they come within the scope of the appended claims and their equivalents.

What is claimed is:

1. An organic light-emitting display device, comprising:
an emission layer formed between two electrodes disposed over a substrate,
wherein the emission layer comprises a host comprising fluorescent materials and a dopant comprising phosphorescent materials, and
a host photoluminescence (PL) region formed by the host of the fluorescent materials has a spectrum overlapped with part of a dopant ultra violet (UV) absorption region formed by the dopant of the phosphorescent materials.

2. The organic light-emitting display device of claim 1, wherein:
an MLCT1 region of the dopant UV absorption region is present within the host PL region, and
only part of an MLCT3 region of the dopant UV absorption region is present within the host PL region.

3. The organic light-emitting display device of claim 1, wherein the host PL region is overlapped with a peak of an MLCT1 region of the dopant UV absorption region and is not overlapped with a peak of an MLCT3 region of the dopant UV absorption region.

4. The organic light-emitting display device of claim 1, wherein a half width of the host PL region is smaller than a half width of an MLCT1 region of the dopant UV absorption region.

5. The organic light-emitting display device of claim 1, wherein the host PL region is partially overlapped with a dopant PL region.

6. The organic light-emitting display device of claim 1, wherein the emission layer comprises a host region, a mixed region of the host and the dopant, and a dopant region.
